(19) United States
(12) Patent Application Publication
(10) Pub. No.: US 2020/0096868 A1
(43) Pub. Date: Mar. 26, 2020

(54) HIGH-RESOLUTION FLEXOGRAPHIC PRINTING PLATE AND MEANS FOR PRODUCING SAME

(71) Applicant: Folex AG, Seewan (CH)

(72) Inventors: Francois VARESCON, Brunnen (CH); Carlfried OSENEGG, Küssnacht Am Rigi (CH); Robert NIGG, Gersau (CH); Felix Bernhard JOHO, Cham (CH)

(21) Appl. No.: 16/612,159

(22) PCT Filed: May 8, 2018
(86) PCT No.: PCT/CH2018/000022

§ 371 Date: Nov. 8, 2019

(30) Foreign Application Priority Data
May 11, 2017 (EP) 17170540,3

(51) Int. Cl. G03F 7/20; G03F 7/016; G03F 7/095; G03F 7/032; B41N 1/12

(52) U.S. Cl. CPC G03F 7/2053; G03F 7/016; B41N 1/12; G03F 7/0325; G03F 7/095

(57) ABSTRACT

The invention relates to a recording element which is suitable for producing high-resolution flexographic printing plates by means of digital information transmission and which can be imaged by means of actinic laser radiation, containing or consisting of the following layers: (A) a carrier film, (B) a photopolymerizable layer/relief layer which can be crosslinked by means of actinic radiation, (C) optionally an intermediate layer which is transparent to actinic radiation as a separating element, and (D) a template layer which is capable of recording and comprises a monomer diazonium compound or (Da) an imaged template layer. The invention likewise relates to a semi-finished product, to a method for producing the recording element, and to a method for producing flexographic printing plates.

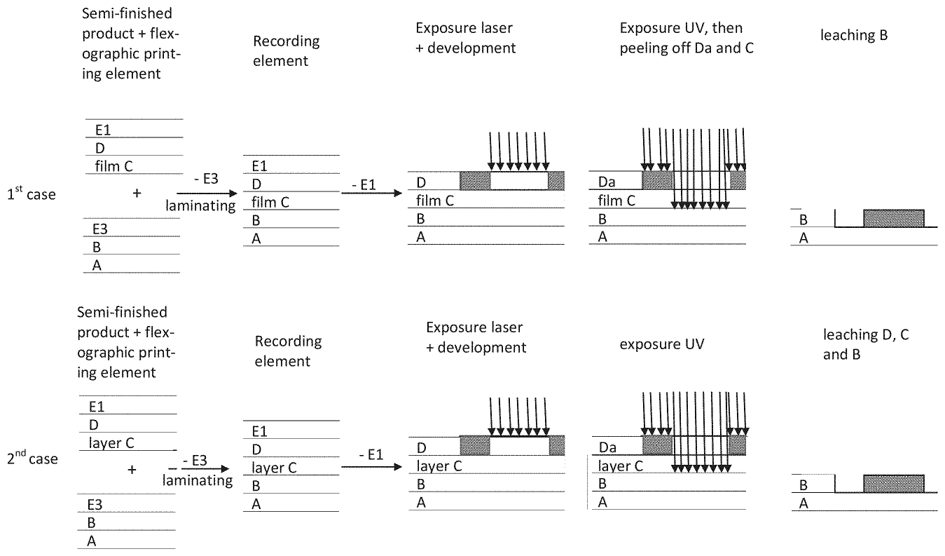

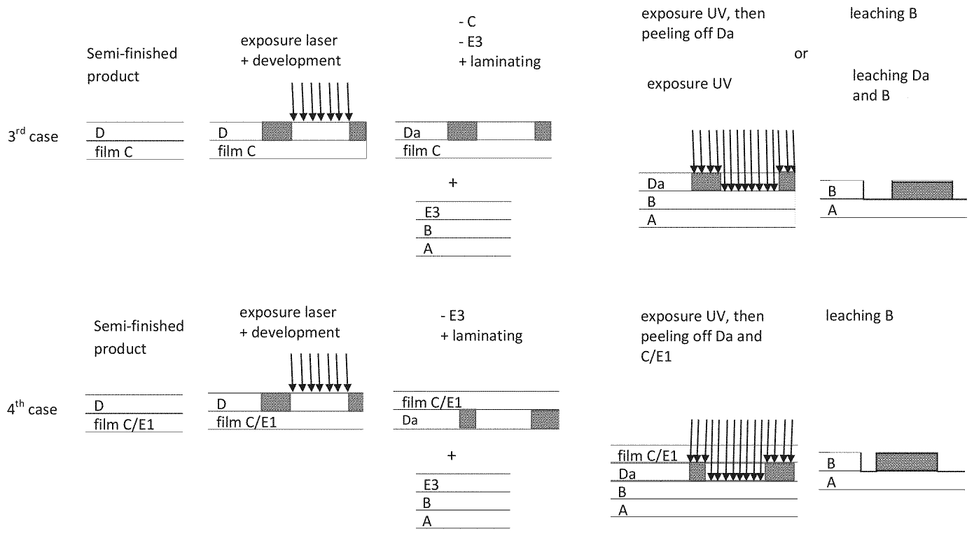

### FIELD OF THE INVENTION

The invention relates to recording elements for the production of high-resolution flexographic printing plates, which are suitable for digital information transmission, as well as means for their production and methods for producing high-resolution flexographic printing plates.

### BACKGROUND

Digital information recordable recording elements are known in principle. They consist—for the production of conventional flexographic printing plates—of at least one support, a photopolymerizable layer as well as a layer capable of recording digital information (recordable template).

From DE 29 23 980 AI multilayer films are known, that, however, are not suitable for digital information transmission with actinic laser radiation; they contain an upper UV transparent carrier film, a first photosensitive layer which polymerizes under UV irradiation, a second photosensitive layer containing as a main component a negative working, water soluble diazonium composition and a hydrophilic carrier film, for example an aluminum film. The exposure of this multilayer film takes place via a transparent mask and the resulting images are obtained by mechanical separation of the layers without further development.

Other radiation-sensitive recording elements are known from DE 103 38 257 A1. Therein two-layer elements are described which have, between a carrier and a cover layer comprising a negative diazo resin, a layer which comprises a polymeric binder that is soluble or swellable in aqueous medium and a radiation-sensitive component. The radiation-sensitive component is either an IR absorber or a compound with a diazo group=N2. If the layer contains an IR absorber, it can be digitally imaged with lasers emitting in the wavelength range from 650 to 1300 nm. If it contains a compound having a diazo group =N2, a conventional UV radiation source which emits radiation of a wavelength in the range from 300 to 450 nm is suitable. As carrier material, for example, an aluminum carrier is described again.

The recordable layer may be, for example, a photopolymer-based layer (see EP 0797120 A2 and EP 0913730 B1), an ink jet-printable layer (see U.S. Pat. No. 7,875,321 B2), a thermographic layer (see DE60,125,755 T2, US2014370440 AI and US2003/211423 A1), a silver halide emulsion layer or a laser-ablatable layer (see US2008258344 Al, W02015040094 A2), the type of recordable layer being responsible for the quality of the reproduction of the low and high tonal values of the printed products.

The layer of digital flexographic printing plates that is decisive for the print is the photopolymerizable layer arranged on a carrier (usually a film of polyethylene terephthalate (PET)). Below, this photopolymerizable layer is also referred to as relief layer, since it results in the final printing plate profile after the washout process. In the preparation of the printing plate profile, the recordable layer plays an important role, since it is responsible for the resolution of the printing plate profile. Among other things, this resolution comprises the reproduction of the fine print elements and the low and high tonal values, in particular in the range of 0 to 5% or 95 to 100% of the screen dots.

The above-mentioned methods with a recordable layer based on an ink-jet printable layer, a thermographic layer or a laser-ablatable layer (also referred to as LAMS (laser ablatable mask layers)) do not show the desired printing results with respect to the reproduction of the fine print elements and the low and high tonal values in the range of 0-5% and 95-100% of the screen dots at high resolution (80 lines/cm, 4400 dpi).

In addition, the exposure technologies used to make the printing plates require two different exposure units, which are an important cost factor in plate making, and in addition, during the exposure processes, oxygen attack occurs, which is enhanced by double exposure.

As already mentioned above, from EP 0797120 A2, the use of a recordable layer based on a photopolymer is known. This layer consists of an arylazophosphonate comprising compound of formula

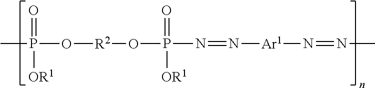

wherein R¹, R², Ar¹ and n have the meaning given in EP 0 797 120 A2, pages 5 and 6.

By exposure by means of actinic laser radiation, the layer having an optical density in the actinic region of >2.5 undergoes a change in the optical density of >1 at the exposed areas under high energy values of >5 up to 50 J/cm².

After exposure or crosslinking, the recordable template layer and the non-crosslinked parts of the relief layer can be removed by means of one or more developers.

Such a recording material shall have the same properties as a recording material according to the comparative example.

A material according to EP 0 797 120 A2 shows the following problems:

The arylazophosphonate containing compounds may be monomeric or oligomeric (n=1 to 10) compounds. In particular, such oligomeric compounds as part of an ablatable layer can be destroyed only with the absorption of high UV radiation (<320 nm). This requires the use of expensive excimer lasers e.g. a XeCl laser (wavelength: 308 nm).

In addition, layers containing arylazophosphonate-containing polymers are unstable and age very rapidly.

The object of the present invention was therefore to provide a recording material suitable for the production of high-resolution flexographic printing plates, that is suitable for digital information transmission and by which at least one, preferably several, in particular all of the following subtasks a) to c) is/are fulfilled:

a) The resolution of the screen dots below the low and above the high tonal values in the range of 0-5% and/or 95-100% is significantly improved. This exceeds the resolution obtainable with conventional plates, known at the end of 2016, for example plates sold by Dupont under the designation Cyrel® Now, using conventional silver halide methods, or laser ablatable (LAMS) layers such as nyloflex® ACE 170 Digital from Flint, CYREL® DSP from Dupont or Digital LUX-ITP from Mac Dermid.

b) The imaging and crosslinking processes are shortened in terms of time.

c) The oxygen attack during the exposure process is reduced, wherein no additional aid, such as nitrogen atmosphere, is needed.

d) It is not necessary to use a laser which generates very short-wave laser radiation (<320 nm).

### DESCRIPTION OF THE INVENTION

Surprisingly, one or more of the abovementioned subtasks, in particular all subtasks a) to c), can be solved by a recordable template layer based on diazonium compounds that are sensitive to actinic laser radiation. Such a recordable template layer may be part of a semi-finished product for the production of a recording material which, as such or after imaging by means of digital information transfer and development, is laminated to the relief layer of a flexographic printing element, or the recordable template layer may be part of a recording element which comprises all layers necessary for the production of a flexographic printing plate. These layers are, in particular, a carrier (A), a conventional photopolymer layer (B) which can be crosslinked by actinic radiation and which is also referred to as a relief layer, a polymer-containing intermediate layer (C) or a thin intermediate film (C), a template layer (D) recordable by means of a digital process and based on diazonium compounds, and optionally a protective film (E1) applied to the layer (D).

In particular, in one aspect, the present invention relates to a recording element which is suitable for the production of high-resolution flexographic printing plates by means of digital information transmission, that can be imagined with actinic laser radiation, which comprises or consists of the following layers arranged one above the other in the stated sequence:

(A) a carrier film, in particular a plastic film, which may optionally be provided with an adhesive layer on the side provided with a photo-polymerizable layer/relief layer,

(B) a photopolymerizable layer/relief layer which is soluble in organic solvents and/or aqueous solvents and which is crosslinkable by actinic radiation,

(C) an actinic radiation transparent intermediate layer or an actinic radiation transparent intermediate film as a separating element,

(D) a recordable template layer comprising a monomeric diazonium compound which is photosensitive to actinic laser radiation and undergoes a change in actinic density by development or an imaged template layer in which the monomeric diazonium compound is destroyed by actinic laser radiation in at least an area and has an increased actinic density in at least one unexposed area due to development.

In addition, the inventive recording element preferably has

(E1) a peelable protective film or cover film disposed on the recordable template layer (D). Such a protective film or cover film may be made of plastic or paper or composite materials.

In a second aspect, the invention relates to a semi-finished product for the production of a recording element, as described above. This comprises at least a film

(C) and/or (E1) and/or (E2) and

(D) a recordable template layer comprising a monomeric diazonium compound which is photosensitive to actinic laser radiation and which undergoes a change in actinic density by means of development, or an imaged template layer in which the monomeric diazonium compound distroyed in at least one area due to actinic laser radiation is destroyed and in at least one unexposed area has an increased actinic density due to developing.

The film (C) is an intermediate layer actinic radiation transparent or an intermediate film actinic radiation transparent and the film (E1) and/or the film (E2) is a protective film or cover film which simultaneously, as well as an intermediate film (C), can perform carrier function. The films (E1) and (E2) may be made of plastic or paper or composite materials. They may be permeable or impermeable to actinic radiation.

Together with a flexographic printing element comprising a carrier film (A), a relief layer (B), optionally an adhesive layer between the relief layer (B) and the carrier film (A) and optionally a peelable protective film or cover film (E3) on the relief layer (B), such semi-finished product can be processed as follows to a recording element:

(i) removing any optionally present protective films or cover films (E2), (E3) from the actinic radiation-transparent intermediate layer (C) or the actinic-radiation-transparent intermediate film (C) and from the relief layer (B),

(ii) optionally removing a protective film or cover film (E1) on the recordable template layer (D),
(iii) optionally imaging the recordable template layer (D) by exposing and developing,

(iv) transferring and laminating the recordable or imaged template layer (D) on the actinic radiation transparent intermediate layer (C) or on the actinic radiation transparent intermediate film (C) onto the relief layer (B) of the flexographic printing element or removing the actinic radiation transparent intermediate layer (C) or the actinic radiation transparent intermediate film (C) and transferring and laminating the imaged template layer (D) onto the relief layer (B) of the flexographic printing element.

A protective film or cover film (E3) optionally present on the flexographic printing element may-like the protective films or cover films (E1), (E2)—also be made of plastic or paper or composite materials.

Also an object of the present invention is a method for the production of high-resolution flexographic printing plates using a recording element of the invention and its imaging by means of digital information transmission using actinic laser radiation. This method comprises the following method steps:

(1) optionally, removing the cover film (E1)

(2)exposing the recordable template layer (D) to actinic laser radiation to form an exposed template layer,

(3) developing the exposed template layer (D) to form an imaged template layer (D),

(4) exposing the recording element provided with the imaged template layer (D) with actinic radiation through the imaged template layer (D),

(5) removing the template layer (D), the optionally present intermediate layer (C), and the not-polymerized portions of the relief-forming layer (B) thus forming the flexographic printing plate,

(6) drying the obtained flexographic printing plate and

(7) optionally and preferably after-treatingof the flexographic printing plate with UV light.

The flexographic printing plate can also be produced starting from an inventive semi-finished product together with a flexographic printing element comprising a relief layer (B), a carrier film (A) and optionally an adhesive layer between the relief layer (B) and the carrier film (A), by imaging by means of digital information transmission using actinic laser radiation. Such a method comprises the steps:

(i) optionally peeling off the cover film (E1) from the semi-finished product,

(ii) exposing the recordable template layer (D) on the actinic radiation transparent intermediate layer or the actinic radiation transparent intermediate film (C) by means of actinic laser radiation to form an exposed template layer (Da),

(iii) developing the exposed template layer (D) to form an imaged template layer (D),
(iv) if appropriate, stripping off a protective film or cover film (E2) possibly present on the transparent intermediate layer or intermediate film (C),

(v) transferring and laminating the imaged template layer (D) on the transparent intermediate layer or intermediate film (C) or the imaged template layer (D) onto the relief layer (B) of a flexographic element comprising this relief layer (B), a carrier film (A) and optionally an adhesive layer between the relief layer (B) and the carrier film (A) to form an imaged recording element,

(vi) exposing the imaged recording element to actinic radiation through the imaged template layer (Da),

(vii) removing the imaged template layer (Da), optionally the intermediate layer or intermediate film (C), and the not polymerized portions of the relief layer (B) using a leaching agent comprising water and/or organic solvents to form the flexographic printing plate,

(viii) drying the resulting flexographic printing plate,

(ix) optionally and preferably after-treating of the flexographic printing plate with UV light.

### BRIEF DESCRIPTION OF THE DRAWINGS

Other embodiments, advantages and applications of the invention will become apparent from the dependent claims and from the

Figure that distinguishes 4 cases, namely

1. Case the production of a flexographic printing plate starting from a semi-finished product with intermediate film (C);

2. Case, the production of a flexographic printing plate starting from a semi-finished product with intermediate layer (C) and protective film (E1 simultaneously serving as carrier film;

3. Case the production of a flexographic printing plate starting from a semi-finished product with intermediate film (C) wherein the exposed and developed template layer (Da) is transferred alone, i.e. without intermediate foil or intermediate layer (C), onto the relief layer of a flexographic printing element, and 4. Case the production of a flexographic printing plate starting from a semi-finished product with intermediate film or protective/cover film (C/E1) wherein the exposed and developed template layer (Da) is transferred onto the relief layer of a flexographic printing element (layer (Da) onto layer (B)), together with the protective/(intermediate) film. The actinic radiation transparent film (C/E1) may remain on the layer (Da) during the exposure process and after the photopolymerization can be peeled off together with the layer (Da) or alone before the leaching of layer (B) and optionally layer (Da).

### WAYS TO CARRY OUT THE INVENTION

The inventive recording element suitable for the production of high-resolution flexographic printing plates by means of digital information transfer that is imageable or imaged with actinic laser radiation contains or consists of the following layers, which are arranged one above the other in the named order:

(A) a carrier film which may optionally be provided with an adhesive layer on the side provided with a photopolymerizable layer/relief layer,

(B) a photopolymerizable layer/relief layer which is soluble in organic solvents and/or aqueous solvents and which is crosslinkable by actinic radiation,

(C) optionally and preferably an actinic radiation transparent intermediate layer or an actinic radiation transparent intermediate film as a separating element,

(D) a recordable template layer comprising a monomeric diazonium compound which is photosensitive to actinic laser radiation and which undergoes a change in actinic density by development, or

(Da) an imaged template layer in which the monomeric diazonium compound is destroyed by actinic laser radiation in at least one area and has an increased actinic density in at least one unexposed area as a result of development.

As protection against pollution, the recording element preferably additionally comprises on the recordable template layer (D),

(E1) a peelable protective foil or cover foil.

The purpose of the recordable layer (D) is its imaging by means of laser radiation and subsequent development process to form a template (mask) for the actinic irradiation of the layer (B) with the desired high resolution. The resolution of the template layer (D) is in the molecular range.

The recordable template layer (D) usually has a layer thickness of 1 μm to 50 μm, preferably from 3 μm to 30 μm, and can be imaged with actinic laser radiation of a power of preferably 10 to 1500 mJ/cm² in the spectral range of 330 nm to 430 nm, in particular from 50 to 1000 mJ/cm² in the specified spectral range.

Preference is given to a recordable template layer (D) which can be developed by means of alkaline solution or alkaline vapors, such as by means of ammonia, in particular ammonia vapor. As a result of the development the unexposed areas become less permeable to the actinic radiation suitable for cross-linking the relief layer. Well suited are materials whose unexposed areas after development have a difference in the actinic density of >3.0.

Preferred recordable template layers consist of at least 70% by weight, preferably at least 85% by weight of a mixture from

(i) at least one binder based on cellulose ester, in particular cellulose acetate propionate (CAP) and/or cellulose acetate butyrate (CAB), and

(ii) at least one diazonium compound of formula (I)

R—N⁺≡N X⁻ (I)

wherein R is a substituted or unsubstituted organic group such as an alkyl group, acyl group or aromatic group,

X⁻ is an anion, in particular selected from the group comprising BF₄⁻, AsF₆⁻, C10₄⁻, SbF₆⁻, CF₃SO₃⁻, SO₄⁻, PF₆⁻ PO₄³⁻, NO₃⁻, Br⁻, Cl⁻, I⁻, F⁻, arylsulfonate, such as p-chlorobenzenesulfonate, alkylsulfonate, allylsulfonate, or a metal complex anion, e.g. ZnCl₃⁻, SnCl₆²⁻,

(iii) in combination with at least one reactive coupler compound.

The ratio polyurethane.

Preferably, R is an aromatic group whose ring is substituted with the substituents Ä, B and C according to formula (Ia) independent of their position to the diazonium group.

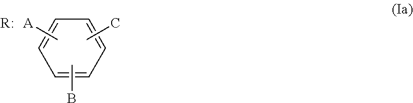

wherein

A, B and C may be the same or different and are selected from the group comprising halogen atom, hydrogen atom, amino groups, thio groups, nitro group, Sulfo group, acyl group, carbalkoxy group, sulfonyl group, cyano group or carboxyl group.

In particular, the groups A, B and C have the following meaning in their preferred ortho, para or meta position to the diazonium group:

A in orthosteposition to the diazonium group is selected from the group comprising halogen atom, hydrogen atom, nitro group, sulfo group or organic group, the organic group being in particular an acyl group, carbalkoxy group, sulfonyl group, cyano group or carboxyl group,

B in para position to the diazonium group is selected from

(i) optionally monosubstituted or disubstituted amino groups, wherein the substituents are each independently selected from the group comprising alkyl groups, aryl groups, alkoxy groups and phenoxy groups, or the two substituents together with the nitrogen to which they are attached form a heterocycle, or

(ii) substituted thio groups wherein the substituent is selected from the group comprising alkyl groups and aryl groups.

C in meta position or in ortho position to the diazonium group is selected from the group comprising acyl groups, carbalkoxy groups, sulfonyl groups, nitro groups, cyano groups, carboxyl groups, sulfo groups, hydrogen or halogen.

An example of a suitable diazo salt is the diazonium compound {Ia) used in the examples with A: Cl, B: N(Et)₂, oder N(Me)_{2;} C: H, X⁻: BF₄⁻ or PF₆⁻.

Unless otherwise stated, all alkyl groups and aryl groups may be substituted or unsubstituted, and the groups listed below in the context of this invention have the meaning:

“Acyl groups” are in particular aliphatic acyl groups with preferably up to about 6 carbon atoms in the alkyl group, for example formyl, acetyl, propionyl, butyryl, β-phenylacetyl and γ-chloropropionyl groups or aromatic acyl groups, such as the benzoyl group;

“Carbalkoxy groups” are in particular alkoxycarbonyl groups having preferably 1 to 8 carbon atoms in the alkoxy group;

“Sulfonyl groups” are, in particular, alkyl-sulfonyl groups, arylsulfonyl groups and aminosulfonyl groups;

“Sulfo groups” are in particular alkylsulfo groups and arylsulfo groups.

For the purposes of the present invention, “alkyl groups” are preferably linear or branched-chain, substituted or unsubstituted alkyl groups with from 1 to about 15 carbon atoms in the alkyl group, such as methyl, ethyl. Suitable substituents are, in particular, halogen atoms, such as chlorine atoms, hydroxyl groups, alkoxy groups with 1 to 5 carbon atoms, such as a methoxy group, phenoxy groups and/or benzylthio groups.

In the context of the present invention, “aryl groups” are preferably to be understood as meaning substituted and unsubstituted monocyclic and polycyclic aromatic groups with 6 to 10 carbon atoms, in particular the phenyl and naphthyl group. Suitable substituents are hydroxy, in particular alkyl groups with 1 to 5 carbon atoms, alkoxy groups with 1 to 5 carbon atoms and halogen atoms.

In the context of this invention suitable groups for R in formula (I) are e.g. as described in DE OS 2 202 251 on pages 3 to 8, and in DE 42 41 717 AI on p. 3, 1. 30 to 46 and p. 4 , 1. 1 to p. 5, 1. 50.

The at least one reactive coupler compound is in particular a coupler compound of the formula (II) or (III)

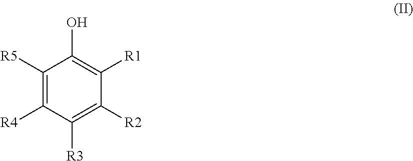

wherein R1, R2, R3, R4 and R5 may be the same or different and are selected from the group comprising —OH, —SO₃H, —CONH—R6 (R6=alkyl, aryl, cycloalkyl, alkoxy), alkoxy group, carboxy group, guanidine group, amino group, acylamido group, thiourea group, thio group, hydrogen or halogen, or

R1 and R2 or R2 and R3 together form a buta-dienyl group such that together with the phenol ring they form a substituted or unsubstituted aromatic bicycle (naphthol structure) according to formula (IIa) or (IIb)

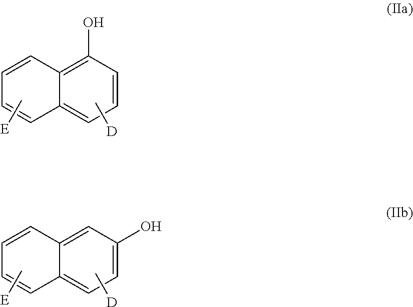

wherein D and E may be the same or different and are selected from the group comprising —OH, —SO₃H, —CONH-R6 (R6=alkyl, aryl, cycloalkyl, alkoxy), alkoxy group, carboxy group, guanidine group, amino group, acylamido group, thiourea group, thio group, hydrogen or halogen,

or

R1 or R2 or R3 are —OH such that an unsubstituted and substituted dihydroxybenzene of formula (IIc), (IId) or (IIe) is present

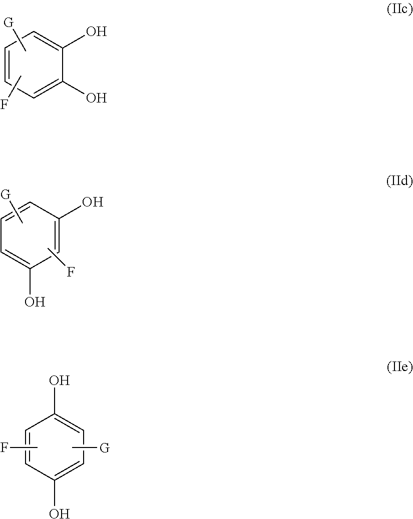

or

R1=R5=—OH or R1=R3=—OH or R2=R4 =—OH, such that an unsubstituted or substituted trihy-droxybenzene of formula (IIf), (IIg) or (IIh) is present

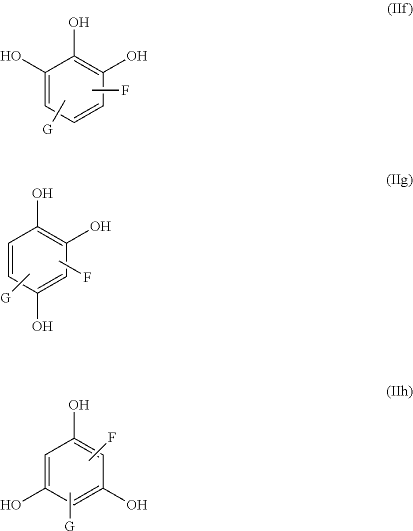

wherein F and G may be the same or different and are selected from the group comprising —OH, —SO₃H, —CONH-R6 (R6=alkyl,aryl, cycloalkyl, alkoxy), alkoxy group, carboxy group, guanidine group, amino group, acyl-amido group, thiourea group, thio group, hydrogen or halogen, e.g.

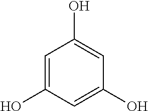

or wherein the coupler compound is a biphenol or bisphenol of formula (III)

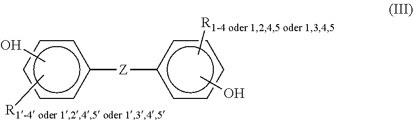

wherein Z=bond, —0— or —S—, and

wherein R1, R2, R3, R4, R5 and R1′, R2′, R3′, R4′, R5′ may be the same or different and are selected from the group comprising —OH, —SO₃H, —CONH—R6 (R6=alkyl, aryl, cycloalkyl, alkoxy), alkoxy group, carboxy group, guanidine group, amino group, acylamido group, thiourea group, thio group, hydrogen or halogen, e.g.

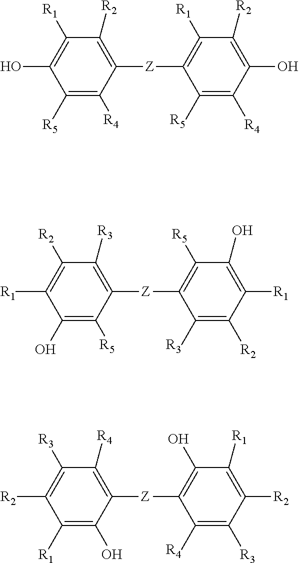

or a corresponding biphenol or bisphenol analogous to the formula (III), with at least 2 OH substituents per phenyl ring, each, wherein the remaining R have the above indicated meaning, e.g

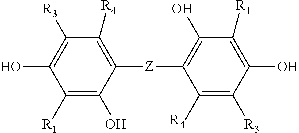

Suitable coupler compounds are e.g. the 3,5-dihydroxybenzoic acid (coupler compound (IId) with F=H and G=(HO)C=0)) and the 2,2′-biphenol (coupler compound (III) with R1 to R4=H, R1′ to R4′ =H and Z=bond) used in the examples.

In addition to the above-mentioned binders, diazonium compounds and reaction couplers, it is possible to add acids to stabilize the template layer (D), e.g. organic acids, such as citric acid, oxalic acid, sulfosalicylic acid, ascorbic acid, sulfonic acid, whose pKa is between 4.0 and 5.0 and that are suitable for adjusting a pH of the final coating solution of below 5.0 (in particular s pH below 3.0). In order to improve the flow properties wetting agents could be added, in order to increase the flexibility of the layer plasticizers could be added, in order to adjust the roughness of the layer surface matting agents, in particular based on silicate, aluminate or polymer, such as polymethyl methacrylate (PMMA), could be adeded and in order to adjust the adhesion properties of the layer crosslinking agents, in particular melamine resin, could be added.

In highly preferred embodiments, the recording element according to the invention has an actinic radiation transparent intermediate layer (C) or an actinic radiation transparent intermediate film (C). Such an intermediate film can serve as a carrier film in a semi-finished, product but the main function of such an actinic radiation-transparent intermediate layer (C) or intermediate film (C) is the clean separation of the relief layer (B) from the recordable template layer (D). It has been found that the diffusion of monomers and additives contained in the relief layer (B) can impair the stability of the recordable layer (D) and its resolution.

A waiver of the intermediate layer/intermediate film (C), however, is e.g. possible if the template layer (D) is already imaged and is applied to the flexographic printing plate on the relief layer (B) only shortly before further processing, so that diffusion processes hardly occur. In a further embodiment, after imaging of the template layer (D), the actinic radiation transparent layer (C), can assume the function of a protective layer (E1) on a recording element, wherein such a protective layer needs not being removed before the exposure of the relief layer.

Usually the actinic radiation transparent intermediate layer (C) or the actinic radiation transparent intermediate film (C) has a thickness of up to 200 μm, such as 0.5 μm to 200 μm, preferably from 1 μm to 100 μm, in particular of 2 μm to 50 μm, more preferably from 3 μm to 15 μm, such as 6 μm.

The actinic radiation transparent intermediate layer (C) consists of at least. 70% by weight, preferably at least 85% by weight of at least one binder, which is based on at least one water-soluble and/or organic solvent-soluble polymer or copolymer and can be removed by water and/or solvent. Such an intermediate layer preferably has a thickness of 3 μm to 15 μm.

Examples of suitable polymers comprise polymers from the class of polyvinyl alcohols, partially or highly hydrolyzed (highly saponified) polyvinyl carboxylates, polyvinyl acetates, poly (ethylene oxide-vinyl alcohol) copolymers or poly (ethylene oxide-vinyl alcohol) copolymers, polyvinyl butyral, polyamide, polyurethane, polyvinylpyrrolidone, (Silicone-polyurethane) copolymers, gelatin or mixtures thereof. Polymers from the group consisting of polyvinyl alcohol, polyvinylpyrrolidone, polyamide, polyurethane, (silicone-polyurethane) copolymers, gelatin and mixtures thereof are preferably suitable. Wetting agents may be added to improve flow properties, to increase flexibility of the layer, plasticizers may be added.

In another embodiment, the recording element comprises an actinic radiation transparent intermediate film (C), which may be mechanically removed from the relief layer (B), in particular peeled off.

Suitable intermediate films (C) are polymer films having a layer thickness of from 1 μm to 50 μm, in particular from 2 μm to 50 μm, such as films of polyester, such as polyethylene terephthalate (PET), polybutylene terephthalate (PBT), polyethylene naphthalate (PEN) and polymethyl methacrylate (PMMA), polyamide or polycarbonate or polyolefins, such as polyethylene (PE), polypropylene (PP), polymethylpentene (PMP) and polybutylene (PB, PIB) or fluoropolymers, such as tetrafluoroethylene (PTFE), polyvinylidene fluoride (PVDF), ethylene tetrafluoroethylene (ETFE), polyvinyl fluoride (PVF) and perfuoroethylene propylene (PEP, FEP) or polyaryl sulfones, such as polyolsulfone (PSU) and polyethersulfone (PES). Particularly suitable are PET films with a thickness of 3 to 15 μm.

The thin intermediate film can optionally, depending on the application, be treated with a conventional adhesion-promoting layer and/or be equipped with a customary adhesive system.

The relief layer (B) of the recording element usually has a layer thickness of 200 μm to 8000 μm, in particular 300 μm to 6000 μm. It contains or consists of a mixture of at least one elastomeric binder, at least two ethylenically unsaturated copolymerizable organic compounds (monomers for the formation of, for example, poly (styrene/isoprene/tyrene) block copolymers) and at least one photoinitiator or a photoinitiator system, as well as, where appropriate, further additives, such as plasticizers.

Commercially available flexographic printing elements of the type (A)+(B)+(E3), which, after removal of the cover film (E3), can be used as part of the recording material of the invention, are available from manufacturers such as Dupont, Flint, Kodak and Fuji under the designation:

Dupont: Cyrel NOW

Flint: Nyloflex ACE 170

Kodak: FLEXCEL NXH plate or Flexcel SR plate

Fuji: Flenex FW

The carrier foil (A) of the inventive recording element usually has a thickness of 50 μm to 300 μm.

Suitable carrier foils (A) are preferably made of plastic, in particular of UV-transparent plastic, such as PET, PBT, PEN, or polycarbonate. Particularly suitable are PET films having a thickness of 50 to 300 μm, preferably 100 to 200 μm. Optionally, the carrier foils (A) may be treated with conventional adhesion-promoting layers.

A further aspect of the invention relates to a semi-finished product for producing a recording element of the invention or for the production of a flexographic printing plate. Such a semi-finished product is characterized by the fact that it contains or consists of

(C) an actinic radiation transparent intermediate layer or an actinic radiation transparent intermediate film as the separating element and optionally carrier,

(D) a recordable template layer comprising a monomeric diazonium compound which is photosensitive to actinic laser radiation and undergoes a change in actinic density by development, or an imaged template layer wherein the monomeric diazonium compound is destroyed in at least one area by actinic laser radiation, and has an increased actinic density in at least one unexposed area due to development.

In one embodiment, the semi-finished product comprises a peelable protective film or cover film (E1) on the recordable template layer (D)

and/or on the actinic radiation-transparent intermediate layer (C) or on the actinic radiation transparent intermediate film (C), in particular on the intermediate layer (C), a peelable protective film or cover film (E2).

Since the actinic radiation transparent intermediate film, e.g. a PET film, is not prone to contamination, its additional protection by another film is usually unnecessary. In contrast, protection of an intermediate layer (C) by a protective or cover film (E2) is often desirable.

A further aspect of the present invention is a process for producing a recording element of the invention using a semi-finished product of the invention and a flexographic printing element comprising a carrier film (A), a relief layer (B), optionally an adhesive layer between the relief layer (B) and the carrier film (A) and optionally a peelable protective film or cover film (E3) on the relief layer (B). The method comprises the following steps:

(i) removing any optionally present protective films or cover films (E2), (E3) from the actinic radiation transparent intermediate layer (C) or of the actinic radiation transparent intermediate film (C) and from the relief layer (B) of the flexographic printing element,

(ii) optionally removing a protective film or cover film (E1) from the recordable template layer (D),

(iii) if necessary, imaging the recordable template layer (D) by exposing and developing,

(iv) transferring and laminating the recordable template layer (D) or the imaged template layer (Da) on the actinic radiation transparent intermediate layer (C) or the actinic radiation transparent intermediate layer (C) onto the relief layer (B) of the flexographic printing element or removing the actinic radiation transparent intermediate layer (C) or the actinic radiation transparent intermediate film (C) and transferring the imaged template layer (D) onto the relief layer (B) of the flexographic printing element.

A further aspect of the present invention relates to a method for producing high-resolution flexographic printing plates using a recording element of the invention and imaging by means of digital information transmission using actinic laser radiation. This method comprises the following method steps:

(1) if necessary, peel off the cover film (E1),

(2) expose the recordable template layer (D) by means of actinic laser radiation to form an exposed template layer,

(3) developing the exposed template layer (D) to form an imaged template layer (D),

(4) exposing the recording element provided with the imaged template layer (D) to actinic radiation through the imaged template layer (D),

(5) removing the template layer (D), the optionally present intermediate layer (C) and the not polymerized portions of the relief-forming layer (B) with forming the flexographic printing plate,

(6) drying the resulting flexographic printing plate and

(7) optionally and preferably after-treating of the flexographic printing plate with UV light.

A further aspect of the present invention is a method for producing high-resolution flexographic printing plates using a semi-finished product of the invention and a flexographic printing element and imaging by means of digital information transmission using actinic laser radiation. This method comprises the following method steps:

(i) if necessary, peeling off the cover film (E1) from the semi-finished product,

(ii) exposing the recordable template layer (D) on the actinic radiation transparent intermediate layer or the actinic radiation transparent intermediate film (C) by means of actinic laser radiation to form an exposed template layer (D),

(iii) developing the exposed template layer (D) to form an imaged template layer (D),

(iv) optionally peeling off a protective film or cover film (E2) optionally present on the transparent intermediate layer or the intermediate film (C) and a protective film or cover film (E3) optionally present on the relief layer (B),

(v) transferring and laminating the imaged template layer (D) on the transparent intermediate layer or intermediate film (C) or the imaged template layer (Da) with or without a transparent intermediate layer or intermediate film (C) onto the relief layer (B) of a flexographic printing element comprising said relief layer (B), a carrier film (A) and optionally an adhesive layer between the relief layer (B) and the carrier film (A), to form an imaged recording element,

(vi) exposing the imaged recording element to actinic radiation through the imaged template layer (D),

(vii) removing the template layer (D), optionally the intermediate layer or intermediate film (C), and the not polymerized portions of the relief layer (B) to form the flexographic printing plate;

(viii) drying the obtained flexographic printing plate,

(ix) optionally and preferably after-treating of the flexographic printing plate with UV light.

In the methods for the production of flexographic printing plates, the template layer (D) that is recordable by means of actinic radiation, usually is exposed to actinic laser radiation of 10 to 1500 mJ/cm² in the spectral range of 330 nm to 430 nm, in particular 50 to 1000 mJ/cm² in the specified spectral range, and after exposure developed by means of alkaline solution or alkaline vapour, such as ammonia, in particular by means of ammonia vapor.

For exposure of the relief layer (B) through the imaged template layer (D) and optionally the actinic radiation transparent layer (C) or intermediate film (C) actinic UV radiation of >5 to 100 J/cm² in a spectral range from 200 nm to 450 nm is suitable.

After exposure of the relief layer to a radiation energy and for a time resulting in the crosslinking of the exposed areas

(i) the imaged template layer (Da), the intermediate layer (C) and the not polymerized parts of the relief layer (B) can be removed by means of a leaching agent containing or consisting of water and/or solvent or

(ii) the intermediate film (C) can be peeled off together with the imaged template layer (Da) and the not polymerized parts of the relief layer (B) can be removed by means of a leaching agent containing or consisting of water and/or solvent.

### EXAMPLES

Preparation of Recording Elements of the Invention

The preparation of the inventive recording elements can be carried out in 3 stages:

1.Production of a flexographic printing element: The components of the photopolyerizable relief layer (B) are applied to a carrier film (A) by means of an extruder. When manufacturing a flexographic printing element, a protective film/cover film (E3) can be laminated to the outside of the relief layer (B). Such a flexographic printing element with or without the protective film/cover film (E3) was used as the starting material for the following examples. Suitable flexographic printing elements are commercially available. In the following examples the flexografic plate Nyloflex ACE 170 from the company Flint was used.

2.A PET film (C/E1) with or without an adhesive layer was coated with the recordable template layer (D). If only one film (C or E1) is present, then it can be laminated as film (C) as intermediate layer onto a photopolymerizable (relief) layer (B) or it may not serve as intermediate film (C), but as protective film and cover film or carrier (E1), respectively, and removed from the template layer (D), such that only the template layer is transferred to the relief layer (B).

3.The recordable or imaged template layer (D, Da) is applied to the flexographic printing element:

1. Case: The intermediate film (C) and/or the protective film and cover film (E1) can act as a carrier here. The intermediate film (C) and the protective film and cover film (E1) are laminated together with the template layer (D) onto the relief layer (B) of a flexographic printing element.

2. Case: Here, the protective film or cover film (E1) acts as a carrier for the template layer (D) and an intermediate layer (C). The protective film or cover film (E1) with the layer (D) and the intermediate layer (C) is laminated onto the flexographic printing element.

3. Case: The film (C) acts as carrier for the template layer {D). A protective film or cover film is not intended or was previously removed. The template layer (D) on the film (C) is exposed to laser radiation and then developed by alkaline solution. Subsequently, the film (C) is laminated onto the flexographic printing element together with the layer (D), such that the imaged template layer (D) is transferred onto the relief layer of the flexographic printing element. Before the UV exposure process, the film (C) is peeled off.

4. Case: The film (C/E1) acts as carrier for the template layer (D). Another protective film or cover film is not intended or was previously removed. The template layer (D) on the film (C/E1) is exposed to laser radiation and then developed by alkaline solution. Subsequently, the film (C) with the imaged template layer (Da) is laminated to the flexographic printing element, such that the imaged template layer (Da) is directly transferred onto the relief layer (B) of the flexographic printing element. The film (C/E1) acts as a protective film/cover film that is transparent to the actinic UV radiation. After the UV exposure process and before the leaching process, the film (C/E1) is peeled off, if appropriate together with the imaged template layer (Da.

Preparation of the Coating Solution of the Imageable Template Layer (D):

56 g of methyl ethyl ketonal and 30 g of methanol were placed in a glass container. Then, 9 g of cellulose acetate propionate (CAP) binder (available from the firm Sigma-Aldrich) were stirred in at room temperature. After 40 minutes, 0.9 g of benzenesulfonic acid (available from the firm Sigma-Aldrich) were stirred in. After 20 minutes, 2.0 g of diazonium compound (Ia))[A: Cl, B: N(Et)₂, or N(Me)₂; C: H, X⁻: BF₄⁻ or PF₆⁻ ](available from the firm Chemos GmbH). 20 Minutes later, 2 coupler compounds (II) were added successively: 0.28 g of 3,5-dihydroxybenzoic acid (coupler compound (IId) with F═H and G═(HO)C═O)) and 1.70 g of 2,2′-biphenol (coupler compound (III) with R1 to R4═H, R1′to R4′ ═H and Z═bond) (obtainable from the firm Aldrich Chemical)) and 0.20 g of a silicone-containing surface additive (BYK-300; obtainablr from the firm BYK).

Preparation of the Coating Solution of the Intermediate Layer (C):

Polyvinylbutyral (Mowital) as Binder

In a glass container, 70 g of iso-propanol were mixed with 20 g of water. Thereafter, 10 g of

Mowital B16H (available from the firm Kuraray) were added and stirred for 60 minutes. The finished solution was ready for use.

Polyvinyl Alcohol as Binder:

In a glass container, 95 g of water were mixed with 0.05 g of Capstonal FS-30 (ethoxylated, nonionic fluoride surfactant). Thereafter, 5 g of polyvinyl alcohol Poval 40-88 partially saponified (available from the firm Kuraray) were added and stirred for 60 minutes. The finished solution was ready for use.

As a flexographic printing agent for the various examples, the plate “nyloflex® ACE 170” from the firm Flint without the recordable layer was used. It consists of a carrier film (A) with about 125 μm thickness and a photopolymerizable relief layer (B) with about 1650-1700 μm thickness and a protective film (E3) with about 125 μm thickness.

### Comparative Example I

A diazofilm DPC-HRP from the firm Folex AG was used as the recordable layer. The imaged template layer was obtained according to process steps a) and b) of example 1 and then copied onto the flexographic printing element nyloflex® ACE 170 (without carbon black containing layer (LAMS)) according to the method step c) of Ex 1.

### Comparative Example II

The recordable layer (D) was a carbon black containing layer (LAMS), which is part of the nyloflex® ACE 170 digital from Flint. The carbon black containing layer was exposed to Multi DX 220 from the firm Luscher. Thereafter, the imaged recording element was exposed and further processed according to method step c) of Ex. 1.

### Comparative Example III

The recordable layer was a carbon black containing layer (LAMS), which is part of Dupont's CYREL® DSP plate. The carbon black containing layer was exposed to Multi DX 220 from the firm Luscher. Thereafter, the imaged recording element was exposed and further processed according to method step c) of Ex. 1.

### Comparative Example IV

The recordable layer was a carbon black containing layer (LAMS), which is part of the digital LUX-ITP plate of Mac Dermid. The carbon black containing layer was exposed to Multi DX 220 from the firm Luscher. Thereafter, the imaged recording was exposed and further processed element according to method step c) of Ex. 1.

### Example 1

The recordable template layer (D) was applied to a thin intermediate film (C) as a release layer and then laminated to the relief layer (B) of the flexographic printing element. (1. Case)

The formulation of the recordable template layer (D) was applied to a 6 μm PET film (C) with an applied amount of approximately 15 g/m² solid and then dried in an oven at a temperature of 130° C. for 2 min. The intermediate film (C) with the layer (D) was stored at room temperature, about 20° C., and 50% relative moisture for at least 24 hours. Due to the production and further processing within the same laboratory premises, covering the recordable template layer (D) with a cover film (E1) was waived. Following storage, the intermediate film (C) with the layer (D)—after removal of the protective film (E3) —was laminated onto the relief layer (B) of the flexographic printing element. An inventive recording element was obtained which is ready for the production of the finished flexographic printing plate.

a) The recording element obtained was exposed to a laser illuminator of the type Multi DX 220 from the firm Luscher with an energy of 500 mJ/cm² at a wavelength of 405 nm and with 2540 dpi and

b) subsequently developed in ammonia vapor (generated from an alkaline solution (25% ammonia) at a temperature of at least 70° C., maximum 95° C.)

c) Thereafter, the printing plate with the template obtained in step b), or the imaged template layer (Da), respectively, was exposed to UV-A radiation by means of a UV exposer of the type Cyrel 2001 E for 50 sec. (base)/600 sec. (front).

d) Subsequently—after peeling off the film (C) together with the layer (D)—the not polymerized areas of the relief layer (B) were leached for 15 min with nylosolv® A from the firm Flint in a Dupont CYREL 3000P processor.

e) The resulting flexographic printing plate was dried for 120 minutes at a temperature of approx. 65° C.

f) Thereafter, the flexographic printing plate was post-exposed:

First about 11 Minutes with UV-C radiation to minimize stickiness at the surface,

then approx. 10 Minutes with UV-A radiation to achieve a sufficient post-curing.

The flexographic printing plate produced in this way was ready for use.

### Example 2

The recordable template layer (D) on a thin film (C/E1) was exposed separately, then developed in alkaline solution, and the developed layer (D) was transferred from the film (C/E1) to the relief layer (B) of the flexographic printing element (3. Case).

The formulation of the layer (D) was applied to a 100 μm PET film (C/E1) without adhesive layer in an applied amount of approx. 15 g/m², then dried in the oven at a temperature of 130° C. for 2 min. and then stored at room temperature, approx. 20° C., and 50% relative humidity for at least 24 hours. This semi-finished product was then exposed to an energy of 500 mJ/cm² at a wavelength of 405 nm and with 2540 dpi by means of a laser of the type Multi DX 220 from the firm Luscher and then developed in ammonia vapor (generated from an alkaline solution (25% ammonia) at a temperature of at least 70° C., maximum 95° C.)

The imaged template layer (Da) was transferred from the substrate (C/E1) onto the relief layer (B) of the flexographic printing element to form an imaged recording element.

Through the mask or the imaged template layer (D), respectively, the resulting recording element was exposed to a UV imagesetter of the type Cyrel 2001 E for 50 sec. (base)/600 sec. (front) and then leached with nylosolv® A from the firm Flint in a Dupont CYREL 3000P processor for 15 min.

The resulting flexographic printing plate was then further processed analogously to Example 1, steps e) and f).

### Example 3

The recordable template layer (D) on a UV-transparent thin carrier film or protective film (C/E1) was exposed separately and subsequently developed in ammonia vapor (produced from an alkaline solution (25% ammonia) at a temperature of at least 70° C., maximum 95° C.) The imaged template layer (Da) prepared in this way was laminated to the relief layer (B) of the flexographic printing element together with the carrier film/protective film (C/E1). (4. Case).

The formulation of layer (D) was applied to a 100 μm-PET film (C/El) without adhesive layer with an applied amount of about 15 g/m² and then dried in the oven at a temperature of 130° C. for 2 min. and then stored at least 24 hours at room temperature, approx. 20 ° C., and 50% relative humidity. This semi-finished product was then exposed to an energy of 500 mJ/cm² at a wavelength of 405 nm and with 2540 dpi by means of a laser image setter of the type Multi DX 220 from the firm Luscher and then developed in ammonia vapor (generated from an alkaline solution (25% ammonia) at a temperature of at least 70° C., maximum 95° C.)

The layer (D) was laminated to the relief layer (B) of the flexographic printing element together with the carrier film/protective film (C/E1) under formation an imaged recording element.

Through the mask or the imaged template layer (Da), respectively, the resulting recording element was exposed to an UV image setter of the type Cyrel 2001 E for 50 sec. (base)/600 sec. (front). After mechanical peeling off of the carrier film/protective film (C/E1) together with the mask (imaged template layer (Da)), the not polymerized areas of the relief layer (B) were leached with nylosolv® A from Flint in a Dupont CYREL 3000P processor for 15 minutes.

The resulting flexographic printing plate was then further processed analogously to Example 1, steps e) and f).

### Example 4

The recordable template layer was applied according to the invention with an intermediate layer as a release layer. (2. Case)

The formulation of the recordable template layer (D) was applied to a 100 μm PET film (E1) without an adhesive layer in an applied amount of about 15 g/m² and then dried in the oven at a temperature of 130° C. for 2 min. Subsequently, the intermediate layer (C), for which Mowital was used as binder, was applied to the layer (D) in an applied amount of about 3 g/m² and dried in the oven at a temperature of 70° C. for 2 min. The thus prepared two-layered material from the recordable template layer (D) and the actinic laser radiation transparent intermediate layer (C) was transferred to the relief layer (B) of the flexographic printing element while simultaneously removing the support film (E1) and to form the recording element.

The recording material prepared in this way was exposed by means of a laser, as described in Example 1, developed in alkaline solution and the photo-polymerizable relief layer was exposed through the mask, or the imaged template layer (Da), respectively. Subsequently, the layers (Da) and (C) and the not polymerized areas of the relief layer (B) were leached with nylosolv® A from the firm Flint in a Dupont processor CYREL 3000P for 15 min.

The resulting flexographic printing plate was then further processed analogously to Example 1, steps e) and f).

### Example 5

The recordable template layer was applied together with an intermediate layer as a release layer according to the invention (2. Case).

The procedure was analogous to Example 5[recte 4], with the difference that as a binder for the intermediate layer (C) polyvinyl alcohol was used instead of Mowital.

Comparison of Comparative Examples I, II, III and IV with Examples 1, 2, 3, 4 and 5 according to the invention

Evaluation

The resulting flexographic printing plates were examined under the microscope at a 30-fold magnification using the imaged UGRA/FOGRA digital plate wedge, the differently imaged font sizes (0.5 pt to 8 pt) as well as the imaged dot sizes and line sharpness (from 20 to 600 μm). The following features were evaluated:

1. Determination of spot size in μm: the imaged spots were measured and evaluated in the microscope and the smallest spot size that was visible and printable was recorded as reference value.

2. Determination of font size in pt: The imaged letters on a scale of 0.5 to 6.0 pt were evaluated under a microscope and the smallest font size, which was judged to be readable and sharp, was recorded as a reference value.

3. Determination of the line width μm: The imaged lines were measured and evaluated in the microscope. The narrowest visible and sufficiently sharp line for print reproduction was taken as the reference value. 4. Determination of the lowest and highest tonal value (%): On the gradient/step wedge (ÜGRA/FOGRA digital plate wedge), the graduated tonal values from 0 to 100% were measured and evaluated by microscope. The smallest and the highest tonal value of the gradient wedge/step wedge with sufficient profile for the print reproduction were taken as reference values.

Results:

| | | | line | |
|---|---|---|---|---|
| | dot size | font size | width | gradient wedge |
| | visible | legible | visible | lowest/highest |
| | from: | from: | from: | tonal value |
| | [μm] | [pt] | [μm] | [%] |
| Example | 1 | 2 | 3 | 4 |
| Comp. I | 100 | 1 | 40 | 3.0/95.0 |
| Comp. II | 100 | 1 (frayed) | 50 | 3.0/97.0 |
| Comp. III | 500 | 2 (frayed) | 100 | 4.0/94.0 |
| Comp. IV | 75 | 1 | 50 | 1.0/97.0 |
| 1 | 40 | 0.5 | 20 | 1.0/97.0 |
| 2 | 40 | 0.5 | 20 | 1.0/97.0 |
| 3 | 40 | 0.5 | 20 | 1.0/97.0 |
| 4 | 40 | 0.5 | 20 | 1.0/97.0 |
| 5 | 40 | 0.5 | 20 | 1.0/97.0 |

The experiments prove that the recording elements of the invention have a high resolution, can image very fine surface structures and exceed the state of the art.

While preferred embodiments of the invention have been described in the present application, it is to be understood that the invention is not limited to these and may be embodied otherwise in the scope of the appended claims.

1. A recording element which is suitable for the production of high-resolution flexographic printing plates by means of digital information transmission, that can be imagined with actinic laser radiation or that is imaged, said recording element comprises or consists of the following layers arranged one above the other in the stated sequence:
(A) a carrier film, optionally provided with an adhesive layer on the side provided with a photopolymerizable layer/relief layer,
(B) a photopolymerizable layer/relief layer which is soluble in organic solvents and/or aqueous solvents and which is crosslinkable by actinic radiation,
(C) optionally an actinic radiation transparent intermediate layer or an actinic radiation transparent intermediate film as a separating element, which may optionally be provided with an adhesive layer on the side provided with a photo-polymerizable layer/relief layer,
(D) a recordable template layer comprising a monomeric diazonium compound which is photosensitive to actinic laser radiation and undergoes a change in actinic density by development or
(Da) an imaged template layer in which the monomeric diazonium compound is destroyed by actinic laser radiation in at least an area and has an increased actinic density in at least one unexposed area due to development.

2. The recording element of claim 1, that comprises
the actinic radiation transparent intermediate layer or the actinic radiation transparent intermediate film (C) as a separating element.

3. The recording element of claim 1 that comprises
the recordable template layer (D) and on this layer additionally
a peelable protective film or cover film (E1).

4. The recording element of claim 1, characterized in that the recordable or imaged template layer (D, Da) has a layer thickness of 1 μm to 50 μm, preferably from 3μm to 30 μm.

5. The recording element of claim 1, wherein the recordable template layer (D) can be exposed with actinic laser radiation of a power of10 to 1500 mJ/cm² in the spectral range from 330 nm to 430 nm, in particular from 50 to 1000 mJ/cm² in the specified spectral range.

6. The recording element of claim 1, wherein the recordable template layer can be developed by means of an alkaline solution or alkaline vapors, like ammonia vapor, such that the unexposed areas become less permeable to actinic radiation, in particular such that the unexposed, developed areas of the recordable template layer have an actinic density >3.0.

7. The recording element of claim 1, wherein the recordable template layer consists of at least 70% by weight, in particular at least 85% by weight of a mixture of at least one cellulose ester-based binder and a diazonium compound and a reactive coupler compound, wherein
the diazonium compound is a diazonium salt according to formula (I),
R—N≡N⁺X⁻ (I)
wherein R is a substituted or unsubstituted organic group such as an alkyl group, acyl group or aromatic group,
X⁻ is an anion, in particular selected from the group comprising BF₄⁻, AsF₆⁻, ClO₄⁻, SbF₆⁻, CF₃SO₃⁻, SO₄⁻, PF₆⁻PO₄³⁻, NO₃⁻, Br⁻, Cl⁻, I⁻, F⁻, arylsulfonate, such as p-chloro-benzenesulfonate, alkylsulfonate, allylsulfonate, or a metal complex anion, e.g. ZnCl₃⁻, SnCl₆²⁻
and the reactive coupler compound is in particular a coupler compound of formula (II), 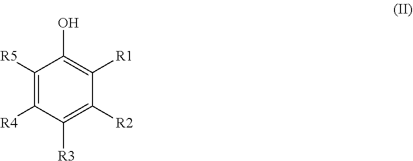
wherein R1, R2, R3, R4 and R5 may be the same or different and are selected from the group comprising —OH, —SO₃H, —CONH-R6 (R6═alkyl, aryl, cycloalkyl, alkoxy), alkoxy group, carboxy group, guanidine group, amino group, acylamido group, thiourea group, thio group, hydrogen or halogen, or
R1 and R2 or R2 and R3 together form a butadienyl group,
and wherein the ratio of binder to diazo compound usually is from 50:1 to 1:2, preferably from 20:1 to 1:1, and the ratio of diazo compound to coupler compound from 4:1 to 1:4, preferably from 2:1 to 1:2.

8. The recording element of claim 1, wherein
the actinic radiation transparen intermediate layer (C) or the actinic radiation transparent intermediate film (C) has a thickness of up to 200 μm, such as 0.5 μm to 200 μm, preferably from 1μm to 100 μm, in particular of 2μm to 50 μm, more preferably from 3μm to 15 μm.

9. The recording element of claim 1, that comprises an actinic radiation transparent intermediate layer (C) that consists of at least 70% by weight, preferably at least 85% by weight of at least one binder which is based on at least one water-soluble and/or organic solvent-soluble polymer or copolymer and can be removed by water and/or solvent, like it comprises polyvinyl alcohols, partially or highly hydrolyzed (highly saponified) polyvinyl carboxylates, polyvinyl acetates, poly(ethylene oxide-vinyl alcohol) copolymers or poly(ethylene oxide-vinyl alcohol) copolymers, polyvinyl butyral, polyurethane, polyvinylpyrrolidone, gelatin or mixtures thereof, in particular polymers from the group consisting of polyvinyl alcohol, polyvinylpyrrolidone, polyamide, polyurethane, gelatin and mixtures thereof

10. The recording element of claim 1, that comprises an actinic radiation transparent intermediate film (C), which may be mechanically removed from the relief layer (B), in particular peeled off, in particular an intermediate film (C) selected from the group consisting of polymer films like polyester, such as polyethylene terephthalate (PET), polybutylene terephthalate (PBT), polyethylene naphthalate (PEN) and polymethyl methacrylate (PMMA), polyamide or polycarbonate or polyolefins, such as polyethylene (PE), polypropylene (PP), polymethylpentene (PMP) and polybutylene (PB, PIB) or fluoropolymers, such as tetrafluoroethylene (PTFE), polyvinylidene fluoride (PVDF), ethylene tetrafluoroethylene (ETFE), polyvinyl fluoride (PVF) and perfuoroethylene propylene (PEP, FEP) or polyaryl sulfones, such as polyolsulfone (PSU) and polyethersulfone (PES), in particular PET films.

11. The recording element of claim 1, wherein the relief layer (B) has a layer thickness of 200 μm to 8000 μm, in particular 300 μm to 6000 μm and/or comprises or consists of at least one elastomeric binder, at least two ethylenically unsaturated copolymerizable organic compounds (monomers) and at least one photoinitiator or a photoinitiator system.

12. A semi-finished product for producing a recording element of claim 1, that contains or consists of the following layers:
(C) an actinic radiation transparent intermediate layer or an actinic radiation transparent intermediate film
(D) a recordable template layer comprising a monomeric diazonium compound which is photosensitive to actinic laser radiation and undergoes a change in actinic density by development, or
(Da) an imaged template layer wherein the monomeric diazonium compound is destroyed in at least one area by actinic laser radiation, and has an increased actinic density in at least one unexposed area due to development.

13. The semi-finished product of claim 12, that comprises
on the recordable template layer (D) a peelable protective film or cover film (E1)
and/or on the actinic radiation transparent intermediate layer (C) or on the actinic radiation transparent intermediate film (C), in particular on the actinic radiation transparent intermediate layer (C), a peelable protective film or cover film (E2).

14. A Method for the production of a recording element according to one of claim 1 using a semi-finished product according to claim 12 and a flexographic printing element comprising a carrier film (A), a relief layer (B), optionally an adhesive layer between the relief layer (B) and the carrier film (A) and optionally a peelable protective film or cover film (E3) on the relief layer (B), characterized in that it comprises the following steps:
(i) removing optionally present protective films or cover films (E2), (E3) from the actinic radiation transparent intermediate layer (C) or actinic radiation transparent intermediate film (C) and from the relief layer (B) of the flexographic printing element,
(ii) optionally removing a protective film or cover film (E1) from the recordable template layer (D),
(iii) optionally imaging the recordable template layer (D) by exposing and developing,
(iv) transferring and laminating the recordable template layer (D) or the imaged template layer (Da) on the actinic radiation transparent intermediate layer (C) or on the actinic radiation transparent intermediate film (C) onto the relief layer (B) of the flexographic printing element or removing the actinic radiation transparent intermediate layer (C) or the actinic radiation transparent intermediate film (C) and transfering the imaged template layer {Da) onto the relief layer (B) of the flexographic printing element.

15. A Method for producing high-resolution flexographic printing plates by using a recording element of claim 1 and by imaging by means of digital information transmission using actinic laser radiation, characterized in that it comprises the following process steps:
(1) optionally peeling off the cover film (E1)
(2) exposing the recordable template layer (D) by means of actinic laser radiation to form an exposed template layer,
(3) developing the exposed template layer to form an imaged template layer (Da),
(4) exposing the recording element provided with the imaged template layer (Da) with actinic radiation through the imaged template layer,
(5) removing the template layer (Da), the optionally present intermediate layer (C) as well as the not polymerized portions of the relief-forming layer (B) to form the flexographic printing plate,
(6) drying the obtained flexographic printing plate and
(7) optionally and preferably after-treating the flexographic printing plate with UV light.

16. A Method for producing high-resolution flexographic printing plates by using a semi-finished product of claim 12 or 13 and by imaging by means of digital information transmission using actinic laser radiation, wherein said method comprises the following process steps:
(i) optionally peeling off the cover film (E1) from the semi-finished product,
(ii) exposing the recordable template layer (D) on the actinic radiation transparent intermediate layer (C) or the actinic radiation transparent intermediate film (C) by means of actinic laser radiation to form an exposed template layer,
(iii) developing the exposed template layer to form an imaged template layer (Da),
(iv) optionally peeling off a protection film or cover film (E2) possibly present on the transparent intermediate layer or intermediate film (C)
(v) transferring and laminating the imaged template layer (Da) on the transparent intermediate layer or intermediate film (C) or the imaged template layer (Da) onto the relief layer (B) of a flexographic printing element comprising this relief layer (B), a carrier film (A) and optionally an adhesive layer between the relief layer (B) and the carrier film (A) to form an imaged recording element,
(vi) exposing the imaged recording element to actinic radiation through the imaged template layer (Da),
(vii) removing the template layer (Da), optionally the intermediate layer or intermediate film (C) and the not polymerized portions of the relief layer (B) to form the flexographic printing plate,
(viii) drying the obtained flexographic printing plate
(ix) optionally and preferably after-treating the flexographic printing plate with UV light.

17. The method of claim 14, wherein the actinic radiation recordable layer (D) is exposed to actinic laser of 10 to 1500 mJ/cm² in the spectral range of 330 nm to 430 nm, in particular from 50 bis 1000 mJ/cm² in the specified spectral range.

18. The method of claim 14, wherein the recordable template layer is developed after exposure by using an alkaline solution or an alkaline vapor, in particular ammonia vapor.

19. The method of claim 15, wherein the relief layer (B) is exposed to actinic radiation of >5 to 100 J/cm² in the spectral range from 200 nm to 450 nm through the imaged template layer (D) and, if appropriate, the actinic radiation transparent intermediate layer or intermediate film (C).

20. The method of claim 15, wherein
(i) the template layer (D), the intermediate layer (C) and the not polymerized parts of the relief layer (B) are removed by means of a leaching agent which contains or consists of water and/or solvent, or that
(ii) the intermediate film (C) is peeled off together with the template layer (D) and the not polymerized parts of the relief layer (B) are removed by means of a leaching agent containing or consisting of water and/or solvent.

21. (canceled)
